(19) United States
(12) Patent Application Publication
(10) Pub. No.: US 2014/0374904 A1
(43) Pub. Date: Dec. 25, 2014

(54) SEMICONDUCTOR DEVICE, SEMICONDUCTOR DEVICE MANUFACTURING METHOD, AND SEMICONDUCTOR MANUFACTURING APPARATUS

(71) Applicant: TOKYO ELECTRON LIMITED, Tokyo (JP)

(72) Inventors: Kenji MATSUMOTO, Nirasaki-shi (JP); Kaoru MAEKAWA, Albany, NY (US); Hiroaki KAWASAKI, Nirasaki-shi (JP); Tatsufumi HAMADA, Nirasaki-shi (JP)

(21) Appl. No.: 14/478,436

(22) Filed: Sep. 5, 2014

Related U.S. Application Data
(63) Continuation of application No. PCT/JP2013/000765, filed on Feb. 13, 2013.

(30) Foreign Application Priority Data
Mar. 8, 2012 (JP) 2012-051271

(51) Int. Cl. H01L 23/482; H01L 21/324; C25D 7/12; C23C 16/06; C23C 16/44; H01L 21/306; H01L 21/48

(52) U.S. Cl. CPC H01L 23/4827; H01L 21/306; H01L 21/324; H01L 21/4814; C23C 16/06; C23C 16/4402; C25D 7/12
USPC 257/741; 438/687; 118/719; 204/232

(57) ABSTRACT

The present disclosure provides a semiconductor device, including: an insulation layer and a wiring line layer, the wiring line layer including a wiring line having a line width and a line height, at least one of which is 15 nm or less, and containing Ni or Co as a main component thereof. In another embodiment, there is provided a semiconductor device manufacturing method for manufacturing a semiconductor device including an insulation layer and a wiring line layer, including: forming the wiring line layer on the insulation layer, the wiring line layer including a wiring line having a line width and a line height, at least one of which is 15 nm or less, and containing Ni or Co as a main component thereof.

This application is a Continuation Application of PCT International Application No. PCT/JP2013/000765, Feb. 13, 2013, which claimed the benefit of Japanese Patent Application No. 2012-051271, Mar. 8, 2012, the entire content of each of which is hereby incorporated by reference.

### TECHNICAL FIELD

The present disclosure relates to a semiconductor device having a thinned wiring line, a manufacturing method of the semiconductor device and a semiconductor manufacturing apparatus of the semiconductor device.

### BACKGROUND

In the related art, miniaturization of semiconductor devices has been progressed. Consequently, a wiring line formed in semiconductor devices has been becoming thinner. However, the thinning of the wiring line leads to an increase in electrical resistance. Moreover, the density of an electrical current flowing through the wiring line is increased. Thus, electromigration (hereinafter referred to as “EM”) can easily occur. Accordingly, use of copper (Cu) having both lower electrical resistance and higher EM resistance than aluminum (Al) as a wiring line material has been proposed.

It is known that, if a wiring line becomes thinner, the electrical resistivity (hereinafter referred to as “resistivity”) is increased. This effect is generally known as a line thinning effect. Copper (Cu) has bulk resistivity of 1.8 μΩ·cm which is right above that of silver. The line thinning effect increases significantly when a wiring line width is 50 nm or less that is closer to a mean free path of an electron. This is because electron scattering generated at a grain boundary or an interface of a wiring line increases, thereby sharply increasing the wiring line resistance. If a wiring line becomes thinner, “wind of electrons” also grows stronger. Thus, atoms are moved and an EM resistance is impaired. Eventually, reliability of a wiring line tends to decrease. In this way, along with the thinning of a wiring line, the deterioration of the line thinning effect and reliability cannot be ignored. Under these circumstances, semiconductor devices that show low electrical resistance, superior EM resistance and high reliability have been demanded even when a wiring line is made thinner.

### SUMMARY

Some embodiments of the present disclosure provides a semiconductor device which can deliver low in electrical resistance of a thinned wiring line, superior in EM resistance and high in reliability, a semiconductor device manufacturing method and a semiconductor manufacturing apparatus.

According to one embodiment of the present disclosure, there is provided a semiconductor device, including: a plurality of insulation layers; and a plurality of wiring line layers, each of the plurality of wiring line layers including a wiring line having a line width and a line height, at least one of which is 15 nm or less, and containing Ni or Co as a main component thereof.

According to another embodiment of the present disclosure, there is provided a method for manufacturing a semiconductor device including an insulation layer and a wiring line layer, including: forming the wiring line layer on the insulation layer, the wiring line layer including a wiring line having a line width and a line height, at least one of which is 15 nm or less, and containing Ni or Co as a main component thereof.

According to another embodiment of the present disclosure, there is provided an apparatus for manufacturing a semiconductor device including an insulation layer and a wiring line layer, including: a first processing chamber configured to form a seed layer containing Ni or Co as a main component thereof on a surface of the insulation layer; a second processing chamber configured to cause a metal layer containing Ni or Co as a main component thereof to grow on the seed layer; a transfer chamber configured to interconnect the first processing chamber and the second processing chamber and kept in a non-oxidizing atmosphere; and a transfer unit arranged within the transfer chamber and configured to transfer the semiconductor device from the first processing chamber to the second processing chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view of a semiconductor device according to one embodiment.

FIGS. 2A to 2C are manufacturing process diagrams of the semiconductor device according to the embodiment.

FIG. 3 is a plane view of a semiconductor manufacturing apparatus according to one embodiment.

FIGS. 4A to 4E are manufacturing process diagrams of a semiconductor device according to a modified example of the embodiment.

FIG. 5 is a view showing measurement results of a film thickness and a resistivity in Example 1 of the embodiment.

FIG. 6 is a view showing measurement results of a film thickness and a resistivity in Example 2 of the embodiment.

FIG. 7 is a view showing measurement results of a film thickness and a resistivity in Example 3 of the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

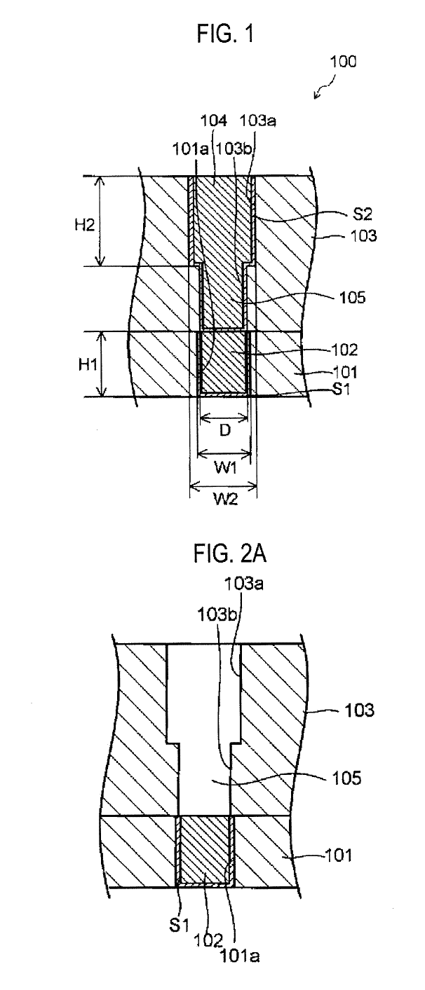

FIG. 1 is a configuration view of a semiconductor device 100 according to one embodiment. The semiconductor device 100 is characterized that wiring lines 102 and 104 having a width and a height, at least one of which is 15 nm (nanometer) or less, and a via-conductor 105 having an outer diameter which is 15 nm or less are formed by a metal or an alloy containing Ni (nickel) or Co (cobalt) as a main component thereof. As will be described later in examples, if at least one of a width and a height of the wiring lines 102 and 104 is 15 nm or less, Cu (copper) is higher in resistivity than Ni (nickel) or Co (cobalt) due to the line thinning effect.

As described above, if the wiring lines 102 and 104 having a width and a height, at least one of which is 15 nm or less, and the via-conductor 105 having an outer diameter which is 15 nm or less are formed by a metal or an alloy containing Ni (nickel) or Co (cobalt) as a main component thereof, it is possible obtain a semiconductor device which is low in electrical resistance of a wiring line. The configuration of the semiconductor device 100 according to one embodiment will now be described with reference to FIG. 1.

The semiconductor device 100 is formed on a semiconductor substrate W (hereinafter referred to as “wafer W”). The semiconductor device 100 includes an inter-layer insulation layer 101, a wiring line 102 (including a seed layer S1) embedded in the inter-layer insulation layer 101, an inter-layer insulation layer 103 formed on the inter-layer insulation layer 101, a wiring line 104 (including a seed layer S2) embedded in the inter-layer insulation layer 103, and a via-conductor 105 (including the seed layer S2) configured to interconnect the wiring lines 102 and 104.

The inter-layer insulation layers 101 and 103 are, e.g., SiO₂ films, TEOS films or Low-K films. In some embodiments, in order to reduce crosstalk between the wiring lines, the inter-layer insulation layers 101 and 103 are Low-K films. Examples of a material of the Low-K films include, e.g., SiC, SiN, SiCN, SiOC, SiOCH, porous silica, porous methylsilsesquioxane, SiLK (registered trademark), BlackDiamond (registered trademark), polyarylene and so on.

The wiring line 102 contains Ni or Co as a main component thereof. The wiring line 102 is embedded in a trench (groove) 101a formed by selectively etching the inter-layer insulation layer 101. At least one of a width W1 and a height H1 of the wiring line 102 is 15 nm or less.

The wiring line 104 contains Ni or Co as a main component thereof. The wiring line 104 is embedded in a trench (groove) 103a formed by selectively etching the inter-layer insulation layer 103. At least one of a width W2 and a height H2 of the wiring line 104 is 15 nm or less.

The via-conductor 105 contains Ni or Co as a main component thereof. The via-conductor 105 is embedded in a via hole 103b formed by selectively etching the inter-layer insulation layer 103. The via-conductor 105 electrically interconnects the wiring lines 102 and 104. An outer diameter D of the via-conductor 105 is 15 nm or less.

### (Manufacture of Semiconductor Device 100)

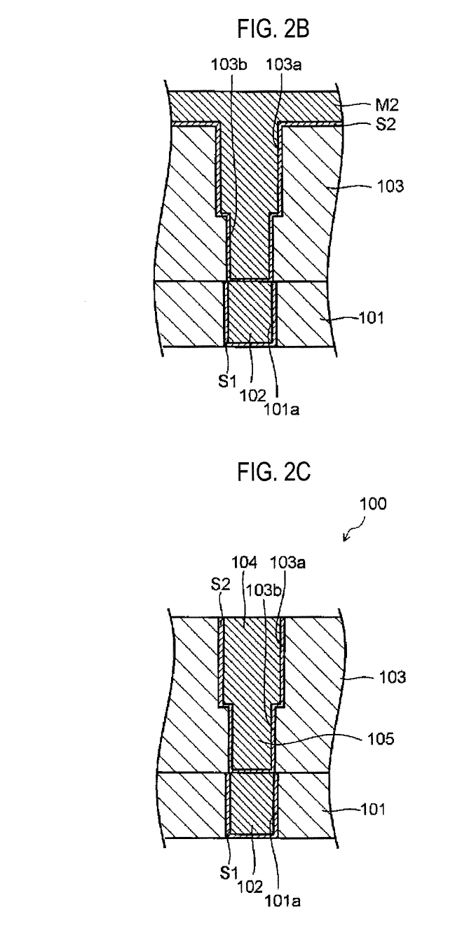

FIGS. 2A to 2C are manufacturing process diagrams of the semiconductor device 100. With reference to FIGS. 2A to 2C, a manufacturing method of the semiconductor device 100 will now be described. In the following description, the manufacturing process of the semiconductor device 100 will be described, assuming that the inter-layer insulation layer 103 has already been formed.

### (First Step: See FIG. 2A)

A trench 103a for embedding the wiring line 104 and a via hole 103b for embedding the via-conductor 105 are formed by selectively etching the inter-layer insulation layer 103.

### (Second Step: See FIG. 2B)

A seed layer S2 and a metal layer M2, both of which contain Ni or Co as a main component thereof, are formed on the surface of the inter-layer insulation layer 103 including the trench 103a and the via hole 103b by a CVD (Chemical Vapor Deposition) method, a PVD (Physical Vapor Deposition) method, an ALD (Atomic Layer Deposition) method, an electroplating method, an electroless plating method, a supercritical CO₂ deposition method or the combination thereof.

When forming the seed layer S2 and the metal layer M2, the seed layer S2 may be formed on the inter-layer insulation layer 103 including the trench 103a and the via hole 103b by, e.g., a PVD method, an ALD method or an electroless plating method, and then, the metal layer M2 may be formed by a CVD method or an electroplating method. Alternatively, the seed layer S2 may be formed by a PVD method, a CVD method, an ALD method or an electroless plating method, and then, the metal layer M2 may be formed by a PVD method, a CVD method, an ALD method or an electroless plating method.

In some embodiments, in order to suppress oxidation, the formation of the seed layer S2 and the formation of the metal layer M2 are performed in a non-oxidizing atmosphere, e.g., in a vacuum (low-pressure) atmosphere or in a reducing atmosphere. The reducing atmosphere can be realized by, e.g., introducing a hydrogen (H₂) gas or a carbon monoxide (CO) gas into a chamber. According to the Ellingham diagram cited in the Steel Handbook, in order to create a Ni reducing atmosphere at a temperature of 200 degree C., it is necessary to control a division ratio of H₂/H₂O so as to become 1/100 or more or to control a division ratio of CO/CO₂ so as to become 1/1000 or more. Thus, in some embodiments, in case where the formation of the seed layer S2 and the formation of the metal layer M2 are performed in a reducing atmosphere, the division ratio of H₂/H₂O is set equal to or greater than 1/100, or the division ratio of CO/CO₂ is set equal to or greater than 1/1000. In case of Co, at a temperature of 200 degree C., a Co reducing atmosphere can be formed with the same division ratio as used in case of Ni. At other temperatures, division ratios may be properly set based on the Ellingham diagram. However, if CO is used in a large amount with respect to Ni, there may be a case where toxic Ni(CO)₄ is formed. For that reason, it is desirable to use a necessary minimum amount of CO.

In some embodiments, an annealing process (heat treatment) is performed after forming the seed layer S2 and the metal layer M2. In this time, if an annealing process is performed for a period of time using a vertical furnace or the like, there is a concern that the seed layer S2 and/or the metal layer M2 are oxidized. For that reason, in some embodiments, the annealing process is performed for a short period of time using a single-wafer processing apparatus. For example, in addition to a single-wafer resistance heating process apparatus, in some embodiments, an RTP process in which lamp light is irradiated only for a short period of time, a laser annealing process in which laser light is irradiated only for a short period of time, or an LED annealing process in which LED (Light Emitting Diode) light is irradiated only for a short period of time is performed. The grain size of Ni or Co as a main component of the seed layer S2 and the metal layer M2 can be controlled by adjusting an annealing process time or an annealing temperature.

### (Third Step: See FIG. 2C)

Next, the seed layer S2 and the metal layer M2 formed on the inter-layer insulation layer 103 are polished and removed by an CMP (Chemical Mechanical Polishing) method, thereby forming a wiring line 104 embedded in the trench 103a and a via-conductor 105 embedded within the via hole 103b. The wafer W polished by the CMP method is cleaned in order to remove residues such as slurry and so forth.

### (Semiconductor Manufacturing Apparatus 200)

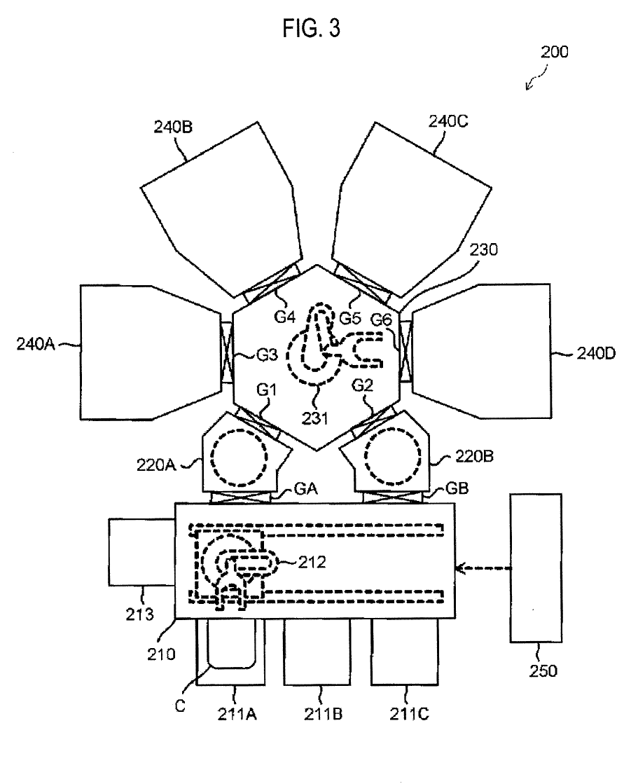

FIG. 3 is a plan view of a semiconductor manufacturing apparatus 200. The configuration of the semiconductor manufacturing apparatus 200 for manufacturing the semiconductor device 100 will now be described with reference to FIG. 3. The semiconductor manufacturing apparatus 200 includes a loader module 210, load lock chambers 220A and 220B, a transfer chamber 230, a plurality of processing chambers 240A to 240D and a control device 250.

### (Loader Module 210)

The loader module 210 includes a plurality of door openers 211A to 211C, a transfer robot 212 and an alignment room 213. Each of the door openers 211A to 211C is configured to open and close a door of an accommodating container C (e.g., an FOUP (Front Opening Unified Pod) or an SMIF (Standard Mechanical Interface) pod) of the wafer W to be processed. The transfer robot 212 is configured to transfer the wafer W among the accommodating container C, the alignment room 213 and the load lock chambers 220A and 220B.

Within the alignment room 213, there is installed an aligner (not shown) for adjusting the position of a notch (or orientation flat) of the wafer W, which is taken out from the accommodating container C, and the eccentricity of the wafer W. In the following description, adjusting the position of the notch (or orientation flat) and the eccentricity of the wafer W will be referred to as an alignment. The wafer W carried out from the accommodating container C by the transfer robot 212 is subjected to the alignment within the alignment room 213 and then transferred to the load lock chamber 220A (or 220B). The door openers 211A to 211C, the transfer robot 212 and the aligner within the alignment room 213 are controlled by the control device 250.

Due to installation of a vacuum pump (e.g., a dry pump) and a leak valve, the load lock chambers 220A and 220B can be switched between an air atmosphere and a vacuum atmosphere. The load lock chambers 220A and 220B include gate valves GA and GB for loading and unloading the wafer W at the side of the loader module 210. When the wafer W is loaded into and unloaded from the load lock chambers 220A and 220B by the transfer robot 212, the load lock chambers 220A and 220B are switched to the air atmosphere, and then, the gate valves GA and GB are opened. The gate valves GA and GB are controlled by the control device 250.

### (Transfer Chamber 230)

The transfer chamber 230 includes gate valves G1 to G6 and a transfer robot 231. The gate valves G1 and G2 are valves for partitioning the load lock chambers 220A and 220B. The gate valves G3 to G6 are valves for partitioning the processing chambers 240A to 240D. The transfer robot 231 performs delivery of the wafer W between the load lock chambers 220A and 220B and the processing chambers 240A to 240D.

A vacuum pump (e.g., a dry pump) and a leak valve are installed in the transfer chamber 230. The interior of the transfer chamber 230 is usually kept in the vacuum atmosphere and is switched to the air atmosphere, if necessary (e.g., maintenance). In order to realize a high degree of vacuum, a TMP (Turbo Molecular Pump) or a Cryo pump may be installed. In order to maintain the interior of the transfer chamber 230 in a reducing atmosphere, a hydrogen gas (H₂ gas) may be introduced into the transfer chamber 230. In this time, the hydrogen gas is introduced into the transfer chamber 230 such that a division ratio of H₂/H₂O becomes equal to or greater than 1/100. During the introduction of the hydrogen gas, an Ar gas containing about 3% of hydrogen may be introduced in consideration of a lower explosion limit. As mentioned above, a reducing atmosphere may be maintained by introducing a carbon monoxide gas instead of the hydrogen gas. In case of introducing the carbon monoxide gas, just like the introduction of the hydrogen gas, an Ar gas containing about 10% of carbon monoxide may be introduced in consideration of a lower explosion limit. The gate valves G1 to G6 and the transfer robot 231 are controlled by the control device 250.

The processing chamber 240A is a degassing chamber. In the processing chamber 240A, the wafer W is heated by a heater or a lamp, thereby removing moisture or organic substances on the surface of the wafer W.

The processing chamber 240B is a seed layer forming chamber. In the processing chamber 240B, a seed film containing Ni or Co as a main component thereof is formed on the surface of the wafer W as a processing target. The processing chamber 240B is, e.g., a PVD chamber or an ALD chamber.

The processing chamber 240C is a depositing chamber. In the processing chamber 240C, a metal layer containing Ni or Co as a main component thereof is formed on the surface of the wafer W as a processing target. The processing chamber 240C is, e.g., a CVD chamber.

The processing chamber 240D is an annealing chamber. In some embodiments, in order to prevent oxidation of the seed layer and the metal layer formed in the processing chambers 240B and 240C, the processing chamber 240D performs an annealing process for a short period of time. For example, in addition to a single-wafer resistance heating process apparatus, the processing chamber 240D may perform one of an RTP process in which lamp light is irradiated only for a short period of time, a laser annealing process in which laser light is irradiated only for a short period of time, and an LED annealing process in which LED (Light Emitting Diode) light is irradiated only for a short period of time. The grain size of Ni or Co as a main component of the seed layer S2 and the metal layer M2 can be controlled by adjusting an annealing process time or an annealing temperature. The annealing process may be performed under a reducing atmosphere by introducing a hydrogen (H₂) gas or a carbon monoxide (CO) gas into the processing chamber 240D. In order to increase the wafer in-plane uniformity, an annealing process pressure can be properly selected at 133 Pa or more, e.g., 1330 Pa.

The control device 250 is, e.g., a computer, and is configured to control the loader module 210, the load lock chambers 220A and 220B, the transfer chamber 230, the processing chambers 240A to 240D and the gate valves GA, GB and G1 to G6 of the semiconductor manufacturing apparatus 200.

### (Manufacture of Semiconductor Device 100 by Semiconductor Manufacturing Apparatus 200)

Next, the manufacture of the semiconductor device 100 by the semiconductor manufacturing apparatus 200 will be described in detail. The manufacture of the semiconductor device 100 by the semiconductor manufacturing apparatus 200 will now be described with reference to FIGS. 2A, 2B and 3. In the following description, it is assumed that, prior to the wafer W being conveyed to the semiconductor manufacturing apparatus 200, the semiconductor device 100 is formed on the wafer W as in the state shown in FIG. 2A.

That is to say, in the process described below, a metal layer containing Ni or Co as a main component thereof is embedded in the trench 103a and the via hole 103b. The via-conductor 105 and the wiring line 104 electrically connected to the wiring line 102 through the via-conductor 105 are formed.

The accommodating container C is conveyed to the semiconductor manufacturing apparatus 200 and is mounted on one of the door openers 211A to 211C. The lid of the accommodating container C is opened by one of the door openers 211A to 211C. Then, the wafer W is taken out from the accommodating container C by the transfer robot 212 and transferred to the alignment room 213. In the alignment room 213, the alignment of the wafer W is performed.

The transfer robot 212 takes out the aligned wafer W from the alignment room 213 and transfers the wafer W to the load lock chamber 220A (or 220B). When transferring the wafer W to the load lock chamber 220A (or 220B), the load lock chamber 220A (or 220B) is kept in the air atmosphere.

After the wafer W is carried into the load lock chamber 220A (or 220B), the gate valve GA (or GB) of the load lock chamber 220A (or 220B) is closed. Thereafter, the load lock chamber 220A (or 220B) is vacuumed to be in the vacuum atmosphere.

After the load lock chamber 220A (or 220B) is switched to the vacuum atmosphere, the gate valve G1 (or G2) is opened. By means of the transfer robot 231, the wafer W is carried into the transfer chamber 230 which is kept in a non-oxidizing atmosphere, e.g., a reducing atmosphere by a H₂ gas or a CO gas. After the wafer W is carried into the transfer chamber 230, the gate valve G1 (or G2) is closed.

Next, the gate valve G3 is opened and the wafer W is carried into the processing chamber 240A by the transfer robot 231. After the gate valve G3 is closed, the wafer W is heated by a heater or a lamp within the processing chamber 240A. Thus, moisture or organic substances adsorbed onto the surface of the wafer W is removed.

Then, the gate valve G3 is opened and the wafer W is carried into the transfer chamber 230 by the transfer robot 231. After the gate valve G3 is closed, the gate valve G4 is opened and the wafer W is transferred into the processing chamber 240B by the transfer robot 231. In the processing chamber 240B, the seed layer S2 containing Ni or Co as a main component thereof is formed on the surface of the inter-layer insulation layer 103 including the trench 103a and the via hole 103b (see FIG. 2B).

Subsequently, the gate valve G4 is opened and the wafer W is carried into the transfer chamber 230 by the transfer robot 231. After the gate valve G4 is closed, the gate valve G5 is opened and the wafer W is transferred into the processing chamber 240C by the transfer robot 231. In the processing chamber 240C, the metal layer M2 containing Ni or Co as a main component thereof is formed on the seed layer S2 by filling the trench 103a and the via hole 103b (see FIG. 2B).

Then, the gate valve G5 is opened and the wafer W is carried into the transfer chamber 230 by the transfer robot 231. After the gate valve G5 is closed, the gate valve G6 is opened and the wafer W is transferred into the processing chamber 240D by the transfer robot 231. In the processing chamber 240D, an annealing process is performed with respect to the seed layer S2 and the metal layer M2 that are formed in the processing chambers 240B and 240C.

Thereafter, the gate valve G6 is opened and the wafer W is carried into the transfer chamber 230 by the transfer robot 231. After the gate valve G6 is closed, the gate valve G1 (or G2) is opened and the wafer W is carried into the load lock chamber 220A (or 220B) by the transfer robot 231.

After the gate valve G1 (or G2) is closed, the load lock chamber 220A (or 220B) is ventilated by CDA or N₂. Accordingly, the interior of the load lock chamber 220A (or 220B) is switched from the vacuum atmosphere to the air atmosphere. Then, the gate valve GA (or GB) is opened and the wafer W is accommodated within the accommodating container C by the transfer robot 212.

If the processing for all the wafers W within the accommodating container C is finished, the accommodating container C is conveyed to a CMP device (not shown) by a conveyance unit (not shown) such as an RGV (Rail Guided Vehicle), an OHV (Overhead Hoist Vehicle) or an AGV (Automatic Guided Vehicle). In the CMP device, the metal layer M2 formed on the inter-layer insulation layer 103 is removed by polishing, thereby forming the wiring line 104 embedded in the trench 103a and the via-conductor 105 embedded within the via hole 103b (see FIG. 2C). The wafer W polished by the CMP method is cleaned in order to remove residues such as slurry and so forth.

As described above, in the present embodiment, the wiring lines 102 and 104 having a width and a height, at least one of which is 15 nm or less, are formed by a metal or an alloy containing Ni or Co as a main component thereof. Thus, as compared with a conventional Cu wiring line, it is possible to reduce electrical resistance of a wiring line. The via-conductor 105 having an outer diameter of 15 nm or less is formed by a metal or an alloy containing Ni or Co as a main component thereof. Thus, as compared with a conventional Cu-made via-conductor, it is possible to reduce electrical resistance of a via-conductor.

Ni or Co is not higher in diffusibility than Cu. Thus, there is no need for a concern about cross contamination between semiconductor manufacturing apparatuses as much as the case for Cu. Hence, it is not necessary to install a dedicated manufacturing line as the case when Cu is used. This increases the degree of freedom for a layout of a semiconductor manufacturing apparatus within a factory. Since there is no need to install a dedicated manufacturing line, it is possible to reduce investment costs in building a manufacturing line.

Inasmuch as the wiring lines 102 and 104 and the via-conductor 105 are formed under a non-oxidizing atmosphere, it is possible to suppress unnecessary oxidation of Ni or Co. Ni or Co reacts with oxygen or moisture, thereby forming an oxide film on the surface thereof and becoming a passive state. Thus, if the wiring lines 102 and 104 and the via-conductor 105 containing Ni or Co as a main component thereof are formed, it is sometimes the case that Ni or Co at an extreme surface layer of the wiring lines 102 and 104 reacts with oxygen or moisture contained in the inter-layer insulation layers 101 and 103, forming a passive state oxide film (barrier film) on an interface of the wiring lines 102 and 104 and the inter-layer insulation layers 101 and 103. The oxide film serves as a barrier that prevents the wiring line from being oxidized by oxygen or moisture generated from the inter-layer insulation layers 101 and 103. This eliminates a step for forming a separate barrier film. Thus, it is expected to simplify the process and reduce the costs. Since the barrier film becomes unnecessary, the increase of effective resistivity attributable to electrical resistivity of the barrier film does not occur. It is therefore possible to reduce the effective resistivity.

If the wiring line 102 and the via-conductor 105 make a direct metal-to-metal connection without going through an oxide film and if the via-conductor 105 and the wiring line 104 make a direct metal-to-metal connection without going through an oxide film, it is possible to reduce electrical resistance of the wiring lines 102 and 104. In some cases, an oxide film is formed such that the wiring line 102 and the via-conductor 105 are connected to each other through the oxide film. In this case, the improvement of electromigration (hereinafter referred to as “EM”) resistance can be expected in that a migration of metal atoms is suppressed at the interface of the wiring line 102 and the via-conductor 105. The oxide film formed at the interface of the wiring line 102 and the via-conductor 105 essentially shows an insulating property but has a small thickness of several nanometers or less. Thus, it is considered that an electrical current flows due to a tunnel effect. Further, barrier films (e.g., TiN, WN, Ti, TaN or Ta films) may be formed between the inter-layer insulation layer 101 and the wiring line 102, between the inter-layer insulation layer 103 and the wiring line 104 and between the inter-layer insulation layer 103 and the via-conductor 105. The melting points of Ni and Co are 1453 degree C. and 1495 degree C., respectively, which are higher than the melting point of Cu, 1083 degree C. Thus, it appears that a wiring line containing Ni or Co as a main component thereof is higher in EM resistance than a wiring line containing Cu as a main component thereof. In addition, the wiring line containing Ni or Co as a main component thereof allows for an increased temperature in a heat treatment that is performed subsequently.

In the semiconductor manufacturing apparatus 200 described above, the seed layer S2 is formed in the processing chamber 240B after a degassing process is performed in the processing chamber 240A. Alternatively, a cleaning chamber may be installed in the semiconductor manufacturing apparatus 200 such that a natural oxide film formed on the surface of the wafer W can be removed by dry etching the surface of the wafer W after performing the degassing process in the processing chamber 240A.

### Modified Example of Embodiment

In the aforementioned embodiment, the steps of manufacturing the semiconductor device 100 (shown in FIG. 1) by a damascene (embedment) method has been described with reference to FIGS. 2A to 2C. In a modified example of the aforementioned embodiment, description will be made on a method for manufacturing a semiconductor device 100 by a subtractive method.

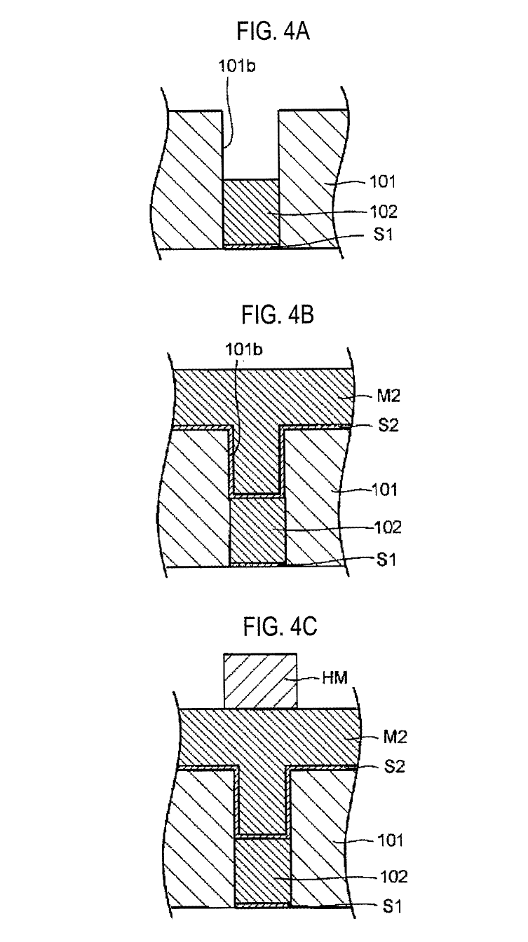

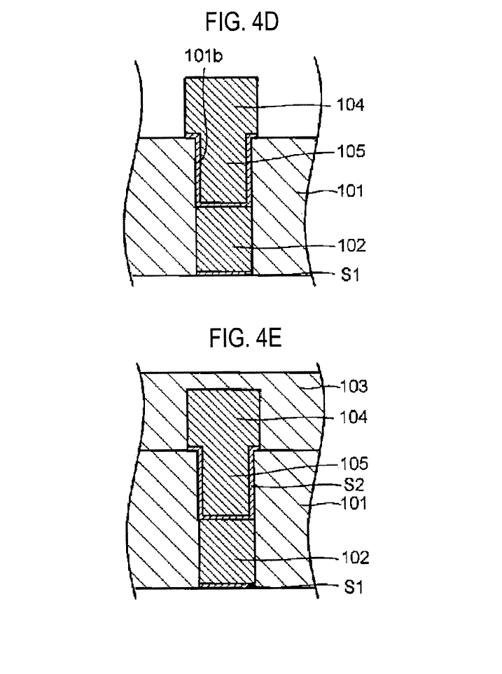

FIGS. 4A to 4E are manufacturing process diagrams of the semiconductor device 100 according the modified example of the embodiment. Steps for manufacturing the semiconductor device 100 by the subtractive method will now be described with reference to FIGS. 4A to 4E. The same components as those described in respect of FIGS. 1 and 2A to 2C will be designated by like reference symbols with repeated description thereon omitted.

### (First Step: See FIG. 4A)

A via hole 101b is formed by selectively etching an inter-layer insulation layer 101.

### (Second Step: See FIG. 4B)

A seed layer S2 and a metal layer M2, both of which contain Ni or Co as a main component thereof, are formed on the surface of the inter-layer insulation layer 101 including the via hole 101b by a CVD method, a PVD method, an ALD method, an electroplating method, an electroless plating method, a supercritical CO₂ film forming method or the combination thereof.

When forming the seed layer S2 and the metal layer M2, the seed layer S2 containing Ni or Co as a main component thereof may be formed on the inter-layer insulation layer 101 including the via hole 101b by, e.g., a PVD method, an ALD method or an electroless plating method, and then, the metal layer M2 may be formed by a CVD method or an electroplating method. Alternatively, the seed layer S2 may be formed by a PVD method, a CVD method, an ALD method or an electroless plating method, and then, the metal layer M2 may be formed by a PVD method, a CVD method, an ALD method or an electroless plating method.

In some embodiments, in order to suppress oxidation, the formation of the seed layer S2 and the formation of the metal layer M2 are performed under the vacuum atmosphere or under a reducing atmosphere. Furthermore, in some embodiments, an annealing process (heat treatment) is performed after forming the seed layer S2 and the metal layer M2.

### (Third Step: See FIG. 4C)

Then, a mask HM is formed on the metal layer M2 in a desired pattern. A material of the mask HM is, e.g., a silicon nitride material (Si₃N₄), a silicon carbide material (SiC), or a silicon oxide material (SiO₂) such as TEOS or the like.

### (Fourth Step: See FIG. 4D)

Then, a via-conductor 105 and a wiring line 104 connected to the via-conductor 105 are formed within the via hole 101b by dry etching.

### (Fifth Step: See FIG. 4E)

Then, an inter-layer insulation layer 103 is formed on the inter-layer insulation layer 101 and the wiring line 104.

### (Manufacture of Semiconductor Device 100 by Semiconductor Manufacturing Apparatus 200)

Next, the manufacture of the semiconductor device 100 by the semiconductor manufacturing apparatus 200 will be described in detail. The manufacture of the semiconductor device 100 by the semiconductor manufacturing apparatus 200 will now be described with reference to FIGS. 3, 4A and 4B. In the following description, it is assumed that, prior to the wafer W being conveyed to the semiconductor manufacturing apparatus 200, the semiconductor device 100 is formed on the wafer W as in the state shown in FIG. 4A.

The accommodating container C is conveyed to the semiconductor manufacturing apparatus 200 and mounted on one of the door openers 211A to 211C. The lid of the accommodating container C is opened by one of the door openers 211A to 211C. Then, the wafer W is taken out from the accommodating container C by the transfer robot 212 and transferred to the alignment room 213. In the alignment room 213, the alignment of the wafer W is performed.

The transfer robot 212 takes out the aligned wafer W from the alignment room 213 and transfers the wafer W to the load lock chamber 220A (or 220B). When transferring the wafer W to the load lock chamber 220A (or 220B), the load lock chamber 220A (or 220B) is kept in the air atmosphere.

After the wafer W is carried into the load lock chamber 220A (or 220B), the gate valve GA (or GB) of the load lock chamber 220A (or 220B) is closed. Thereafter, the load lock chamber 220A (or 220B) is vacuumed to be in the vacuum atmosphere.

After the load lock chamber 220A (or 220B) is switched to the vacuum atmosphere, the gate valve G1 (or G2) is opened. By means of the transfer robot 231, the wafer W is carried into the transfer chamber 230 which is kept in a non-oxidizing atmosphere, e.g., a reducing atmosphere by a H₂ gas or a CO gas. After the wafer W is carried into the transfer chamber 230, the gate valve G1 (or G2) is closed.

Next, the gate valve G3 is opened and the wafer W is carried into the processing chamber 240A by the transfer robot 231. After the gate valve G3 is closed, the wafer W is heated by a heater or a lamp within the processing chamber 240A. Thus, moisture or organic substances adsorbed onto the surface of the wafer W is removed.

Then, the gate valve G3 is opened and the wafer W is carried into the transfer chamber 230 by the transfer robot 231. After the gate valve G3 is closed, the gate valve G4 is opened and the wafer W is transferred into the processing chamber 240B by the transfer robot 231. In the processing chamber 240B, the seed layer S2 containing Ni or Co as a main component thereof is formed on the surface of the inter-layer insulation layer 101 including the via hole 101b (see FIG. 4B).

Subsequently, the gate valve G4 is opened and the wafer W is carried into the transfer chamber 230 by the transfer robot 231. After the gate valve G4 is closed, the gate valve G5 is opened and the wafer W is transferred into the processing chamber 240C by the transfer robot 231. In the processing chamber 240C, the metal layer M2 containing Ni or Co as a main component thereof is formed on the seed layer S2 by filling the via hole 101b (see FIG. 4B).

Then, the gate valve G5 is opened and the wafer W is carried into the transfer chamber 230 by the transfer robot 231. After the gate valve G5 is closed, the gate valve G6 is opened and the wafer W is transferred into the processing chamber 240D by the transfer robot 231. In the processing chamber 240D, an annealing process is performed with respect to the seed layer S2 and the metal layer M2 formed in the processing chambers 240B and 240C.

Thereafter, the gate valve G6 is opened and the wafer W is carried into the transfer chamber 230 by the transfer robot 231. After the gate valve G6 is closed, the gate valve G1 (or G2) is opened and the wafer W is carried into the load lock chamber 220A (or 220B) by the transfer robot 231.

After the gate valve G1 (or G2) is closed, the load lock chamber 220A (or 220B) is ventilated by CDA or N₂. Thus, the interior of the load lock chamber 220A (or 220B) is switched from the vacuum atmosphere to the air atmosphere. Then, the gate valve GA (or GB) is opened and the wafer W is accommodated within the accommodating container C by the transfer robot 212.

If the processing for all the wafers W within the accommodating container C is finished, the accommodating container C is conveyed to other apparatuses, e.g., a coater apparatus, a photolithography apparatus, a developer apparatus, an etching apparatus and a CVD apparatus (all of which are not shown) by a conveyance unit (not shown) such as an RGV, an OHV or an AGV. Then, a mask HM is formed in a desired shape (see FIG. 4C) and dry etching is performed. Thus, a via-conductor 105 and a wiring line 104 connected to the via-conductor 105 are formed within the via hole 101b (see FIG. 4D). Thereafter, an inter-layer insulation layer 103 is formed on the inter-layer insulation layer 101 and the wiring line 104 (see FIG. 4E).

As described above, in the modified example of the aforementioned embodiment, the semiconductor device 100 is manufactured by the subtractive method. Thus, as compared with the damascene method, the grain size of Ni or Co of which the wiring line 104 is made to become larger. The reason is as follows. In the damascene method, a wiring line material is embedded in a trench which is formed in advance. Consequently, the crystal growth of the wiring line material depends on the width of the trench (restrained by a spatial limitation). In contrast, the spatial limitation does not exist in the subtractive method. Thus, the crystal growth of the wiring line material is not hindered when performing an annealing process. If the crystal growth is accelerated and if the grain boundary decreases, electron scattering generated in the grain boundary is also reduced. Accordingly, it is expected that electrical resistance of a wiring line becomes smaller. Moreover, it is expected that EM resistance is further improved. Since a trench (groove) for embedding the wiring line 104 needs not to be formed at the inter-layer insulation layer 103, it is possible to reduce plasma damage to the inter-layer insulation layer 103. Other effects remain the same as those of the semiconductor device 100 according to the aforementioned embodiment.

### Other Embodiments

While one embodiment of the present disclosure has been described above, the present disclosure is not limited to the aforementioned embodiment but may be modified in many different forms. In the semiconductor manufacturing apparatus 200 described with reference to FIG. 3, there are assumed vacuum atmospheric apparatuses in which the internal pressure of the respective processing chambers 240A to 240D is lower than atmospheric pressure. For that reason, a PVD chamber or an ALD chamber is used as the processing chamber 240B configured to form the seed layer S2 and a CVD chamber is used as the processing chamber 240C configured to form the metal layer M2. However, the present disclosure is not limited thereto.

Further, an electroless plating apparatus and an electroplating apparatus may be connected to each other. The seed layer S2 may be formed by the electroless plating apparatus, and then, the metal layer M2 may be formed by the electroplating apparatus. In addition, as described above, the seed layer S2 may be formed by a PVD method, an ALD method or an electroless plating method, and then, the metal layer M2 may be formed by a CVD method or an electroplating method. Even if the above modification is made, it is preferred that the formation of the seed layer S2 and the formation of the metal layer M2 are performed under a non-oxidizing atmosphere.

In a portion where both the width and the height of the wiring lines 102 and 104 exceed 15 nm, it is preferable to use a conventional Cu wiring line. The wiring lines 102 and 104 containing Ni or Co as a main component thereof may further contain elements other than the main component, Ni or Co. The elements other than the main component may include not only Mo, W and Cu, which are reviewed at this time, but also elements capable of forming a passive state film, e.g., Al, Fe, Cr, Ti, Ta, Nb, Mn and Mg. An alloy made of Ni and Co may be used. In that case, the content ratio of Ni and Co can be properly selected from between 0 to 100%. That is to say, if the chemical formula of the alloy is NiₓCo₁₋ₓ, x may take a value of from 0 to 1. When x=0, Ni is 0% and Co is 100%. When x=0.5, both Ni and Co are 50%. When x=1, Ni is 100% and Co is 0%.

Ni or Co is a magnetic (ferromagnetic) material and is higher in relative permeability than Cu. Thus, it is considered that crosstalk becomes a problem if a distance between wiring lines is short. In case where the crosstalk does matter, it is conceivable to reduce the grain size of Ni or Co of which a wiring line is made. Reducing the grain size suppresses magnetization of Ni or Co. Therefore, it is expected that the crosstalk between wiring lines is suppressed.

In this case, for example, Ni or Co is deposited such that the metal layer M2 (see FIGS. 2B and 4B) becomes micro-crystal or amorphous. For an example of the deposition method, it is considered to add Si (silicon) or B (boron) when Ni or Co is deposited. Si (silicon) or B (boron) is called a glass forming atom. By adding an atom differing in size from Ni or Co, Ni or Co can be suppressed to go through crystallization.

It is also considered to deposit Ni or Co in the presence of magnetic fields. By depositing Ni or Co in the presence of magnetic fields, it is expected that the magnetization direction of Ni or Co thus deposited is made uniform. In this case, the magnetic fields are formed such that the magnetization direction becomes parallel to the longitudinal direction of a wiring line. If the magnetization direction is made parallel to the longitudinal direction of a wiring line, it is expected that the influence of the crosstalk will be reduced. In addition, Ni or Co may be used in a wiring line of a device having a high operation frequency (e.g., 1 MHz or more). This is because, even when a material having high relative permeability is used, the influence of magnetization becomes smaller if the operation frequency is high. For example, the relative permeability of Ni and Co is 600 μr and 250 μr, respectively. According to the Snoek's limit line, it is known that, if the frequency becomes about 1 MHz when the relative permeability is about several hundred pr, the magnetic permeability is sharply decreased. The Snoek's limit line refers to a phenomenon that magnetic permeability sharply decreases together with a sharp increase of loss at or around a specific frequency determined by physical properties. The specific frequency becomes lower as the magnetic permeability becomes higher. In general, the product of the magnetic permeability and the threshold frequency remains constant (cited from Ceramics 42 (2007) p 460).

Next, the present disclosure will be described in more detail based on examples. The present inventors formed a plurality of metal films differing in film thickness on a TEOS (450 nm)/Si substrate by a sputtering method at room temperature through the use of different materials (Cu, Co, Mo, W and Ni) and measured the sheet resistance (surface resistivity) of the metal films by a four-terminal method. Furthermore, the film thickness was measured using an XRF (X-ray Fluorescence Analysis) and a TEM (Transmission Electron Microscope). The resistivity of each of the metal films was calculated from the sheet resistance and the film thickness thus measured. The reasons for selecting Co, Mo, W and Ni as substituent materials of Cu are that: 1) Co, Mo, W and Ni are low in bulk resistivity; 2) Co, Mo, W and Ni are high in melting point as one index of EM resistance; and 3) Co, Mo, W and Ni are high in chemical stability (oxidation resistance is high or the surface becomes a passive state). The respective examples will now be described.

### Example 1

By using each of Cu, Co, Mo, W and Ni, a plurality of metal films differing in film thickness was formed. Then, the film thickness and resistivity of each of the metal films were measured. The film thickness was measured using an XRF.

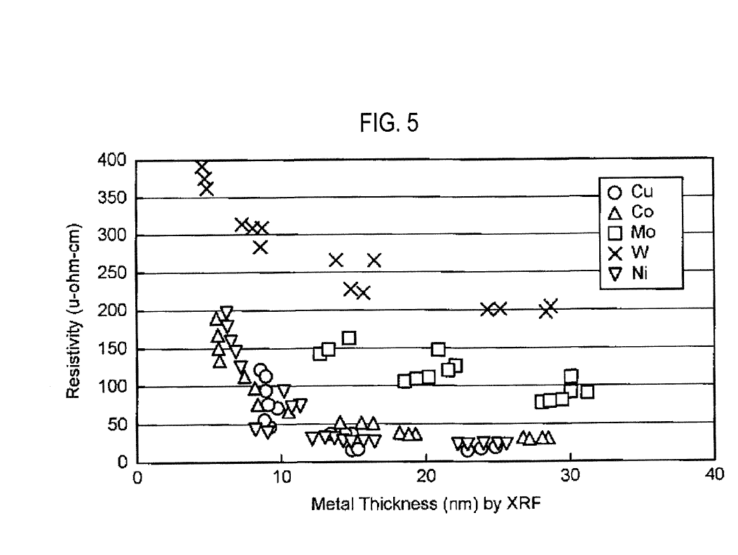

FIG. 5 is a view showing measurement results of the film thickness and the resistivity of Example 1. The vertical axis indicates the resistivity (μΩ·cm) and the horizontal axis indicates the film thickness (nm). As shown in FIG. 5, the resistivity of Ni is higher than the resistivity of Cu in the region where the film thickness is larger than 15 nm. However, the resistivity of Ni is lower than the resistivity of Cu in the region where the film thickness is equal to or smaller than 15 nm.

### Example 2

By using each of Cu, Co, Mo, W and Ni, a plurality of metal films differing in film thickness was formed and then annealed under a reducing atmosphere at 400 degree C. for 30 minutes. The annealing process was performed by creating a reducing atmosphere through the use of a nitrogen (N₂) gas containing 3% of hydrogen (H₂) gas. After the annealing process, the film thickness and resistivity of each of the metal films were measured. The film thickness was measured using an XRF.

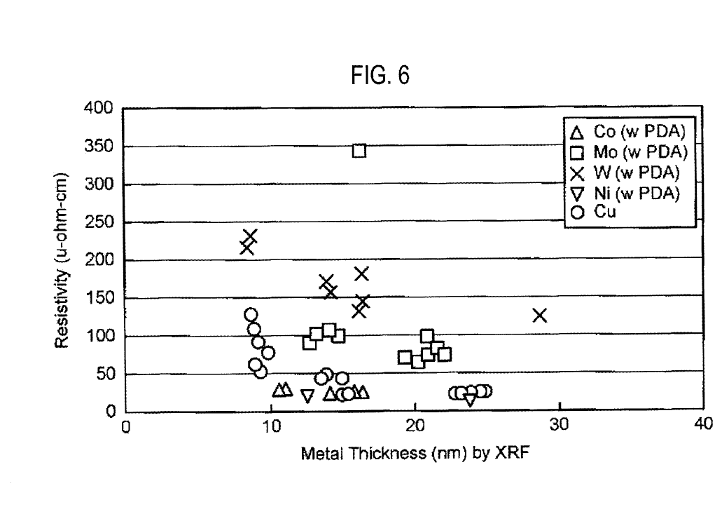

FIG. 6 is a view showing measurement results of the film thickness and the resistivity of Example 2. The vertical axis indicates the resistivity (μΩ·cm) and the horizontal axis indicates the film thickness (nm). In Example 2, the resistivity of Cu could not be measured by a four-terminal method. Presumably, this is because Cu is agglomerated by the annealing process (Cu has a melting point lower than that of Ni or Co) and cannot be maintained in a thin film state. In FIG. 6, the film thickness and resistivity of Cu without an annealing process are shown for comparison.

As shown in FIG. 6, it can be noted that, if the annealing process is performed, the resistivity of Co, Mo, W and Ni tends to be decreased in overall. For example, the resistivity of Ni is substantially equal to the resistivity of Cu in the region where the film thickness is larger than 15 nm. The resistivity of Ni is lower than the resistivity of Cu in the region where the film thickness is equal to or smaller than 15 nm. In case of Co, the resistivity of Co is lower than the resistivity of Cu in the region where the film thickness is equal to or smaller than 15 nm.

### Example 3

By using each of Cu, Co, Mo and Ni, a plurality of metal films differing in film thickness was formed. Then, the film thickness and resistivity of each of the metal films were measured. The film thickness was measured using a TEM.

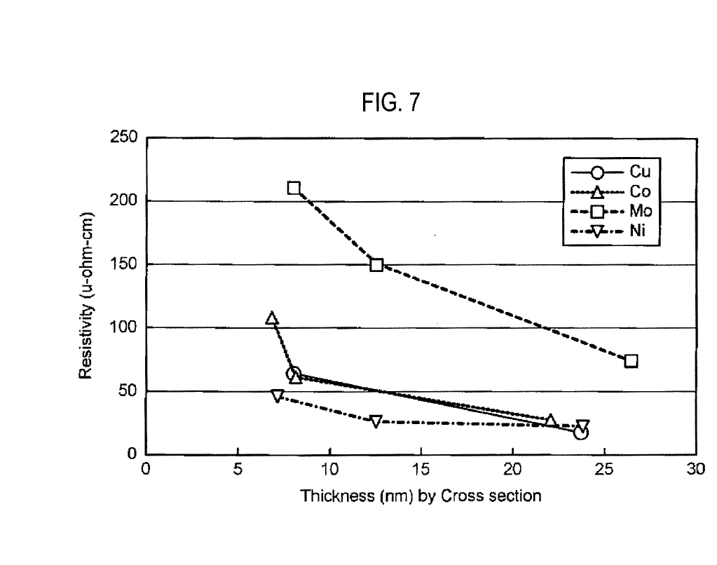

FIG. 7 is a view showing measurement results of the film thickness and the resistivity of Example 3. The vertical axis indicates the resistivity (μΩ·cm) and the horizontal axis indicates the film thickness (nm). As shown in FIG. 7, the resistivity of Ni is lower than the resistivity of Cu in the region where the film thickness is equal to or smaller than 24 nm. In case of Co, the resistivity of Co is substantially equal to the resistivity of Cu in the region where the film thickness is equal to or smaller than 15 nm.

### (Evaluation Result)

The results of Examples 1 to 3 reveal that, Ni or Co (subjected to annealing process) is superior to Cu, W or Mo as a material used for the wiring line, of which at least one of a line width and a line height is 15 nm or less. The reasons for these results are that: Ni or Co is possibly larger in grain size than Cu, W or Mo; Ni or Co is possibly more uniform in grain orientation than Cu, W or Mo; internal oxidation is possibly suppressed in Ni or Co due to formation of a passive state film. The present experiments were not conducted by actually forming a wiring line but were conducted by using a metal thin film. However, the major cause of increased resistivity of a thin film is that the influence of a surface or an interface becomes relatively strong together with thinning of a film and thereby increasing scattering of electrons, the cause which is identical to the major cause of increased resistivity of a fine wiring line.

According to the present disclosure in some embodiments, it is possible to provide a semiconductor device which is low in electrical resistance of a thinned wiring line, a semiconductor device manufacturing method and a semiconductor manufacturing apparatus. Thus, the semiconductor device, the manufacturing method of the semiconductor device and the semiconductor manufacturing device of the present disclosure retain industrial applicability.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a plurality of insulation layers; and
a plurality of wiring line layers,
each of the plurality of wiring line layers including a wiring line having a line width and a line height, at least one of which is 15 nm or less, and containing Ni or Co as a main component thereof.

2. The device of claim 1, further comprising:
a via-conductor configured to interconnect the wiring lines of the plurality of wiring line layers, the via-conductor having a diameter of 15 nm or less and containing Ni or Co as a main component thereof,
wherein the plurality of wiring line layers are formed one above another with one of the plurality of insulation layers interposed therebetween.

3. The device of claim 1, wherein the Ni or the Co has an average grain size of 15 nm or more.

4. The device of claim 1, wherein in case the wiring line layer includes a wiring line having a width and a height of greater than 15 nm, the wiring line contains Cu as a main component thereof.

5. A semiconductor device manufacturing method for manufacturing a semiconductor device including an insulation layer and a wiring line layer, comprising:
forming the wiring line layer on the insulation layer, the wiring line layer including a wiring line having a line width and a line height, at least one of which is 15 nm or less, and containing Ni or Co as a main component thereof.

6. The method of claim 5, wherein the wiring line layer is formed in a non-oxidizing atmosphere.

7. The method of claim 6, wherein the non-oxidizing atmosphere is a vacuum atmosphere or a reducing atmosphere.

8. The method of claim 5, further comprising:
performing a heat treatment to the wiring line layer.

9. The method of claim 8, wherein the heat treatment is a RTP process, a laser annealing process or a heat treatment using an LED.

10. The method of claim 8, wherein the heat treatment is performed by a single-wafer-type annealing apparatus.

11. The method of claim 5, further comprising:
performing a degassing process of the insulation layer by heating before forming the wiring line layer.

12. The method of claim 5, further comprising:
forming a recess portion by selectively etching the insulation layer;
forming a metal layer containing Ni or Co as a main component thereof on a surface of the insulation layer including the recess portion; and
forming the wiring line by removing the metal layer formed on the surface of the insulation layer other than the recess portion.

13. The method of claim 5, further comprising:
forming a metal layer containing Ni or Co as a main component thereof on a surface of the insulation layer; and
forming the wiring line by selectively etching the metal layer.

14. The method of claim 12, wherein forming the metal layer comprises:
forming a seed layer containing Ni or Co as a main component on the surface of the insulation layer; and
causing the metal layer containing Ni or Co as a main component to grow on the seed layer.

15. The method of claim 5, wherein the wiring line is formed by performing one of a CVD method, a PVD method, an ALD method, an electroplating method, an electroless plating method, a supercritical CO₂ film forming method or the combination thereof.

16. The method of claim 5, wherein in case the wiring line layer includes a wiring line having a width and a height of greater than 15 nm, the wiring line is formed by containing Cu as a main component thereof on a surface of the insulation layer.

17. An apparatus for manufacturing a semiconductor device including an insulation layer and a wiring line layer, comprising:
a first processing chamber configured to form a seed layer containing Ni or Co as a main component thereof on a surface of the insulation layer;
a second processing chamber configured to cause a metal layer containing Ni or Co as a main component thereof to grow on the seed layer;
a transfer chamber configured to interconnect the first processing chamber and the second processing chamber and kept in a non-oxidizing atmosphere; and
a transfer unit arranged within the transfer chamber and configured to transfer the semiconductor device from the first processing chamber to the second processing chamber.

18. The apparatus of claim 17, wherein the non-oxidizing atmosphere is a vacuum atmosphere or a reducing atmosphere.

19. The apparatus of claim 17, further comprising:
a third processing chamber connected to the transfer chamber and configured to perform a degassing process by heating the insulation layer prior to forming the wiring line layer.
